(19) United States
(12) Patent Application Publication
(10) Pub. No.: US 2026/0032992 A1
(43) Pub. Date: Jan. 29, 2026

(54) INTEGRATED STRUCTURE OF MOS TRANSISTORS HAVING DIFFERENT OPERATION VOLTAGES AND METHOD FOR MAKING THE SAME

(71) Applicant: Shanghai Huali Integrated Circuit Corporation, Shanghai (CN)

(72) Inventors: Qiwei Wang, Shanghai (CN); Yaoyu Zhan, Shanghai (CN); Xiaoliang Tang, Shanghai (CN); Zhigang Zhang, Shanghai (CN); Haoyu Chen, Shanghai (CN)

(73) Assignee: Shanghai Huali Integrated Circuit Corporation, Shanghai (CN)

(21) Appl. No.: 18/828,301

(22) Filed: Sep. 9, 2024

(30) Foreign Application Priority Data
Jul. 26, 2024 (CN) 202411019198.8

(51) Int. Cl. H01L 27/088; H01L 21/265; H01L 21/8234; H01L 29/10; H01L 29/423; H01L 29/66; H01L 29/78

(52) U.S. Cl. CPC H10D 84/83; H01L 21/26513; H10D 30/022; H10D 30/601; H10D 62/371; H10D 64/514; H10D 64/518; H10D 84/0142; H10D 84/0144; H10D 84/0151; H10D 84/0156; H10D 84/038

(57) ABSTRACT

The present application discloses a method for making an integrated structure of an MOS transistor having different operation voltages. The resulting integrated structure of an MOS transistor employs a hybrid gate solution. A resulting low voltage MOS transistor adopts a high-K metal gate, so that the gate leakage of the LV (low voltage) MOS transistor can be reduced and speed performance is maintained; and a resulting medium voltage MOS transistor and a high voltage MOS transistor adopt a poly gate, the gate oxide is a single oxide, and a high-K film (HK film) is not present, so that the resulting medium voltage MOS transistor and high voltage MOS transistor are highly reliable without any other reliability problems due to the introduction of a high-K film (HK film) and a gate metal film.

### CROSS-REFERENCE TO RELATED APPLICATIONS

This application claims priority to Chinese patent application No. 202411019198.8, filed on Jul. 26, 2024, the disclosure of which is incorporated herein by reference in its entirety.

### TECHNICAL FIELD

The present application relates to semiconductor manufacturing technology, in particular, to an integrated structure of an MOS transistor having different operation voltages and the method for making the same.

### BACKGROUND

Cell phone screens are getting larger, and has been gradually developed as foldable screens, causing a higher requirement for the power consumption and display performance of a display driver chip. Since AMOLED (Active-matrix organic light-emitting diode) screens has built-in advantages, such as a thin panel thickness, high display color saturation, power saving due to low power consumption, and enabling flexible display, the AMOLED screens will be preferred for mid-to-high-end smartphones.

AMOLED driver chips have device properties of the following categories:
(i) due to speed and power consumption requirements, a core LV (low voltage) device requires a low operation voltage (a few tenths of a volt, or a few volts), and a high speed;
(ii). to drive TFT (Thin Film Transistor), an HV (High Voltage) device is required, which has an operation voltage of 20 V-32 V; and
(iii). for current drive circuits, a MV (Medium Voltage) devices is required, which has an operation voltage of 6 V-10 V.

For 28 nm-HV display drivers, it has been a mainstream solution to develop HV and MV device processes in 28 nm HKMG (High-K Metal Gate) platform.

A current 28 nm HV platform, which is a metal gate structure, has additional slots to prevent a metal gate dishing effect of a metal gate, and due to the introduction of metal and high-K constant (High-K, HK) materials, HV and MV devices of the metal gate structure may have poorer reliability than that of the device having a conventional polycrystalline silicon gate structure.

### BRIEF SUMMARY

The method for making an integrated structure of an MOS transistor having different operation voltages, comprising the following steps:
S1. forming a pad-oxide 102 on a silicon substrate 100;
S2. forming a first SIN layer 104 on the pad-oxide 102;
S3. performing a shallow trench isolation process to form a shallow trench isolation 105 dividing a high voltage region, a medium voltage region, and a low voltage region on the silicon substrate 100;
S4. forming a high voltage region si-recess 106 in the silicon substrate 100 in the high voltage region;
S5. performing high voltage gate oxide growth, the upper surface of a high voltage gate oxide 107 in the high voltage region si-recess 106 being flush with the upper surface of the silicon substrate 100;
S6. forming a second SIN layer 108 on the silicon substrate 100;
S7. removing the second SIN layer 108 in the medium voltage region and retaining the second SIN layer 108 in the low voltage region and the high voltage region;
S8. forming a medium voltage region si-recess 109 in the silicon substrate 100 in the medium voltage region, the depth of the medium voltage region si-recess 109 in the silicon substrate 100 being less than that of the high voltage region si-recess 106;
S9. performing medium voltage gate oxide growth, the upper surface of the medium voltage gate oxide 110 within the medium voltage region si-recess 109 being flush with the upper surface of the silicon substrate 100;
S10. removing the second SIN layer 108;
S11. depositing a first polysilicon layer 111;
S12. forming a first hard mask layer 112 on the first polysilicon layer 111;
S13. performing dry etching to remove the first polysilicon layer 111 in the low voltage region; and then depositing a low voltage gate oxide and high-K constant layer 113;
S14. deposing a second polysilicon layer 114 and forming a second hard mask layer 115 on the second polysilicon layer 114, the thickness of the second polysilicon layer 114 being consistent with that of the first polysilicon layer 111, and the thickness of the second hard mask layer 115 being consistent with that of the first hard mask layer 112;
S15. performing photoetching, and etching, removing the second polysilicon layer 114 in the medium voltage region and the high voltage region, and retaining the second polysilicon layer 114 in the low voltage region;
S16. performing photoetching, and etching, and forming a low voltage region gate stack, a medium voltage region gate stack and a high voltage region gate stack; the heights of the low voltage region gate stack, medium voltage region gate stack and high voltage region gate stack being consistent; the low voltage region gate stack including, from bottom to top, the pad-oxide 102, the low voltage gate oxide and high-K constant layer 113, the second polysilicon layer 114, and the second hard mask layer 115; the medium voltage region gate stack including, from bottom to top, the medium voltage gate oxide 110, the first polysilicon layer 111, and the first hard mask layer 112; and the high voltage region gate stack including, from bottom to top, the high voltage gate oxide 107, the first polysilicon layer 111, and the first hard mask layer 112;
S17. forming spacers of the low voltage region gate, the medium voltage region gate, and the high voltage region gate; and
S18. performing a subsequent process to form an integrated structure of an MOS transistor having different operation voltages.

In some examples, step S18 comprises the following steps:
S180. exposing the upper surface of the second polysilicon layer 114 of the low voltage region gate, the upper surface of the first polysilicon layer 111 of the medium voltage region gate, and the upper surface of the first polysilicon layer 111 of the high voltage region gate;
S181. sequentially depositing a first contact etch stop layer 117, and interlayer dielectric 0 118;
S182. performing chemical mechanical polishing, and stopping at the first contact etch stop layer 117;
S183. performing photoetching, and etching, removing the first contact etch stop layer 117 on the medium voltage region gate and the high voltage region gate, exposing the first polysilicon layers 111 of the medium voltage region gate and the high voltage region gate, and retaining the first contact etch stop layer 117 on the low voltage region gate;
S184. performing a metal silicide process to form a gate metal silicide 119 on the exposed first polysilicon layers 111 of the medium voltage region gate and the high voltage region gate;
S185. performing wet etching to remove the first contact etch stop layer 117 on the low voltage region gate;
S186. depositing a second contact etch stop layer 120;
S187. performing photoetching, and etching, removing the second contact etch stop layer on the low voltage region gate and retaining the second contact etch stop layer 120 on the polysilicon layers of the medium voltage region gate and the high voltage region gate;
S188. by a dummy poly removal process, removing the second polysilicon layer 114 on the low voltage region gate and exposing low voltage gate oxide and high-K constant layer 113 deposition at the low voltage region;
S189. performing a metal gate loop and filling a gate metal 121 into the groove of the low voltage region gate surrounded by the low voltage gate oxide and high-K constant layer 113 deposition along with a spacer;
S190. depositing interlayer dielectric 1 122;
S191. performing a contact process, and a subsequent back-end-of-line process, to form an integrated structure of an MOS transistor having different operation voltages.

In some examples, in step S1, the pad-oxide 102 is further formed with a zero mark as an alignment layer for subsequent layer photoetching.

In some examples, in step S2, ion implantation is first performed in the silicon substrate 100 in the high voltage region to form a high voltage region well 1031, and then the first SIN layer 104 is formed on the pad-oxide 102.

In some examples, in step S3, the shallow trench isolation 105 is formed, and then chemical mechanical polishing is performed.

In some examples, in step S4, the high voltage region si-recess 106 has the depth of 400 Å-500 Å in the silicon substrate 100.

In step S9, the medium voltage region si-recess 109 has the depth of 100 Å-200 Å in the silicon substrate 100.

In some examples, in step S6, the first SIN layer 104 is first removed, then ion implantation is performed for the silicon substrate 100 in the medium voltage region and the low voltage region to form the medium Voltage region well 1032 and the low voltage region well 1033, and finally, the second SIN layer 108 is formed on the silicon substrate 100.

In some examples, in step S6, the first SIN layer 104 is first removed, then ion implantation is performed for the silicon substrate 100 in the medium voltage region and the low voltage region to form the medium Voltage region well 1032 and the low voltage region well 1033, then ion implantation is performed for a medium voltage region Lightly-Doped drain 1034 and a high voltage region Lightly-Doped drain 1035, and finally, the second SIN layer 108 is formed on the silicon substrate 100.

In some examples, in step S11, doping ion implantation is performed for the first polysilicon layer 111.

In some examples, the first hard mask layer 112 is a laminated structure of SiN and silicon oxide; and the second hard mask layer 115 is a laminated structure of SiN and silicon oxide.

In some examples, in step S17, ion implantation for a low voltage lightly-doped drain is performed first, then spacers for the low voltage region gate, the medium voltage region gate, and the high voltage region gate are formed; then a source-drain N heavily-doped ion implantation is performed; and finally, a source-drain metal silicide 116 is formed.

In some examples, in step S189, the metal gate loop comprises work function layer and metal deposition.

In some examples, in step S190, chemical mechanical polishing is first performed for the gate metal 121, the gate in the medium voltage region, and the high voltage region stop at the second contact etch stop layer 120, and the low voltage region gate stops at the interlayer dielectric 0 118; and then the interlayer dielectric 1 122 is deposited.

In some examples, the first contact etch stop layer 117 and the second contact etch stop layer 120 are both SiN.

In some examples, the method is a method for making an integrated structure of an MOS transistor having different operation voltages based on a 28HKMG process platform.

The present application provides an integrated structure of an MOS transistor having different operation voltages, the structure having a high voltage MOS transistor, a medium voltage MOS transistor, and a low voltage MOS transistor formed on the same silicon substrate 100;
the operation voltage of the high voltage MOS transistor is greater than that of the medium voltage MOS transistor, and the operation voltage of the medium voltage MOS transistor is greater than that of the low voltage MOS transistor;
the gate stack structure of the high voltage MOS transistor includes a high voltage gate oxide 107, and a first polysilicon layer 111 stacked sequentially from bottom to top; and
the high voltage gate oxide 107 is formed in the silicon substrate 100, and the upper surface of the high voltage gate oxide 107 is flush with the upper surface of the silicon substrate 100;
the gate stack structure of the medium voltage MOS transistor includes a medium voltage gate oxide 110, and a first polysilicon layer 111 stacked sequentially from bottom to top; the medium voltage gate oxide 110 is formed in the silicon substrate 100, and the upper surface of the medium voltage gate oxide 110 is flush with the upper surface of the silicon substrate 100; and the thickness of the medium voltage gate oxide 110 is less than that of the high voltage gate oxide 107; and the gate stack structure of the low voltage MOS transistor comprises a pad-oxide 102,
and a gate metal 121 stacked sequentially from bottom to top; and the pad-oxide 102 covers the upper surface of the silicon substrate 100.

In some examples, the gate stack structure of the low voltage MOS transistor comprises the pad-oxide 102, a low voltage gate oxide and high-K constant layer 113 deposition, and a gate metal 121 stacked sequentially from bottom to top; and the pad-oxide 102 covers the upper surface of the silicon substrate 100.

In some examples, the gate end of the high voltage MOS transistor is connected to the upper end of the first polysilicon layer 111 of the gate stack structure thereof by means of a contact hole;

the gate end of the medium voltage MOS transistor is connected to the upper end of the first polysilicon layer 111 of the gate stack structure thereof by means of the contact hole; and
the gate end of the low voltage MOS transistor is connected to the upper end of the gate metal 121 of the gate stack structure thereof by means of the contact hole.

In some examples, the upper ends of the first polysilicon layers 111 of the gate stack structures of the gate ends of the high voltage MOS transistor and medium voltage MOS transistor are formed with the gate metal silicide 119;
the gate end of the high voltage MOS transistor is connected to the upper end of the gate metal silicide 119 on the gate stack structure thereof by means of the contact hole; and
the gate end of the medium voltage MOS transistor is connected to the upper end of the gate metal silicide 119 on the gate stack structure thereof by means of the contact hole.

In some examples, the high voltage gate oxide 107 has a thickness of 400 Å-500 Å and the medium voltage gate oxide 110 has a thickness of 100 Å-200 Å.

In the method for making an integrated structure of an MOS transistor having different operation voltages of the present application, the resulting integrated structure of an MOS transistor employs a hybrid gate solution. A resulting LV (low voltage) MOS transistor adopts HKMG (High-K Metal Gate), so that the gate leakage of the LV (low voltage) MOS transistor can be reduced and speed performance is maintained; and a resulting MV (medium voltage) MOS transistor and a HV (high voltage) MOS transistor adopt a poly gate, the gate oxide is a single oxide, and a high-K film (HK film) is not present, so that the resulting MV (medium voltage) MOS transistor and HV (high voltage) MOS transistor are highly reliable without any other reliability problems due to the introduction of a high-K film (HK film) and a gate metal film. The method for making an integrated structure of an MOS transistor having different operation voltages is an integrated process method for making an integrated structure of high voltage, medium voltage and low voltage MOS transistors by means of a 28HKMG (28 nm High-K Metal Gate) process platform, effectively improving the compatibility of the high-speed performance of the LV (low voltage) MOS transistor with the high reliability of the MV (medium voltage) MOS transistor and HV (high voltage) MOS transistor made by the same process platform in the same process, and the method can be used for making a highly reliable AMOLED (Active-matrix organic light-emitting diode) display driver chip.

### BRIEF DESCRIPTION OF THE DRAWINGS

To illustrate the technical solution of the present application, the figures which need to be used in the application are briefly stated below. It is obvious that the figures in the following description are only some embodiments of the present application. And a person of ordinary skill in the art may arrive at other figures based on the figures without the exercise of inventive effort.

FIGS. 1-28 are structural schematic diagrams of a making process of an embodiment of a method for making an integrated structure of an MOS transistor having different operation voltages in the present application.

The reference numbers are described below.
100 silicon substrate; 102 pad-oxide; 1031 high voltage region well; 1032 medium voltage region well; 1033 low voltage region well; 1034 medium voltage region Lightly-Doped drain; 1035 high voltage region Lightly-Doped drain; 104 first SIN layer; 105 shallow trench isolation; 106 high voltage region Si-recess; 107 high voltage gate oxide; 108 second SIN layer; 109 medium voltage region Si-recess; 110 medium voltage gate oxide; 111 first polysilicon layer; 112 first hard mask layer; 113 low voltage gate oxide and high-K constant layer; 114 second polysilicon layer; 115 second hard mask layer; 116 source-drain metal silicide; 117 first CESL (Contact Etch Stop Layer); 118 interlayer dielectric 0; 119 gate metal silicide; 120 second CESL (Contact Etch Stop Layer); 121 gate metal; 122 interlayer dielectric 1.

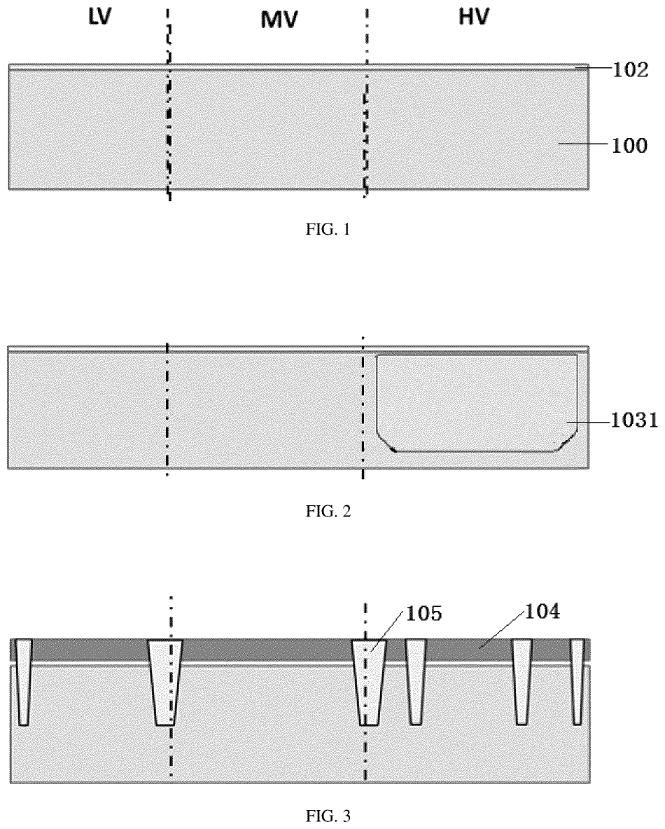

The high voltage region well 1031 is shown only in FIGS. 2, 6, and 18, and is omitted in other figures.

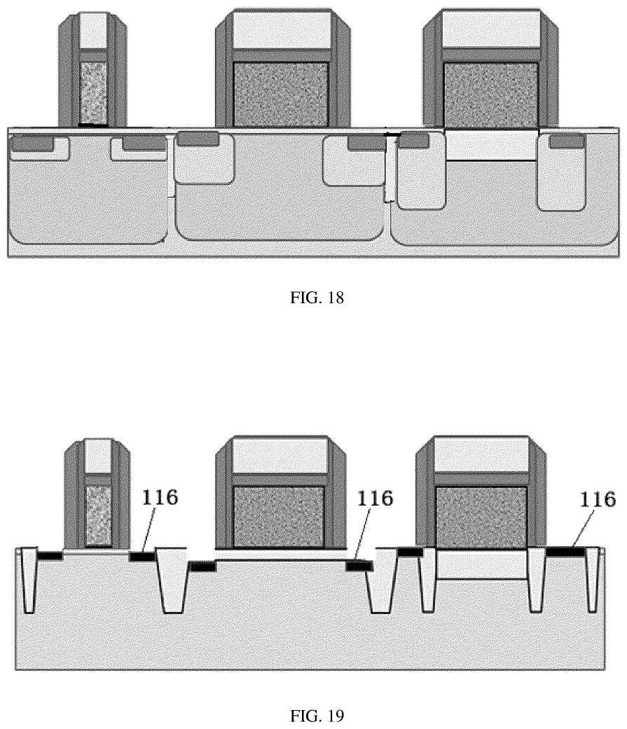

The medium Voltage region well 1032, low voltage region well 1033, medium voltage region Lightly-Doped drain (LDD) 1034, and high voltage region Lightly-Doped drain 1035 are shown only in FIG. 6 and FIG. 18, and are omitted in other figures.

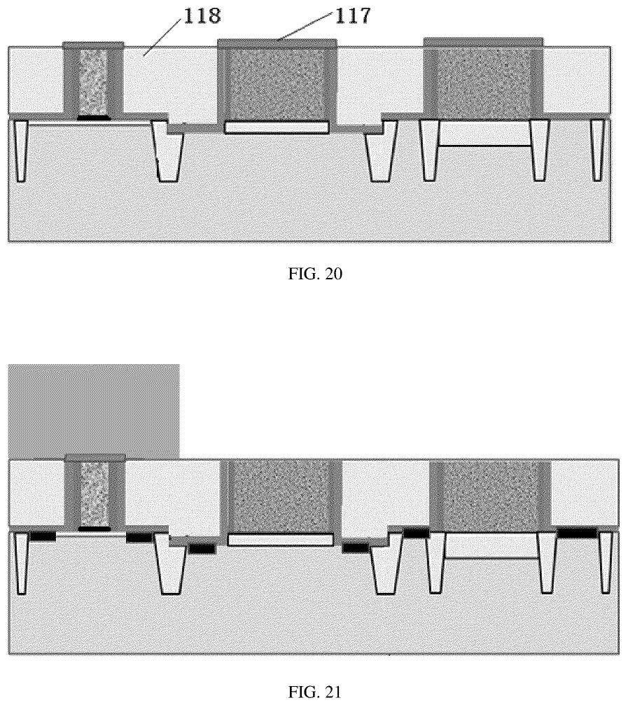

The source-drain metal silicide is omitted in FIG. 20.

### DETAILED DESCRIPTION OF THE DISCLOSURE

The technical solutions in the embodiments of the present application will be clearly described below in conjunction with the figures in the embodiments. Obviously, the described embodiments are only some of the embodiments of the present application, not all of them. Based on the embodiments of the present application, all other embodiments obtained by a person of ordinary skill in the art without the exercise of inventive effort fall within the scope of protection of the present application.

Terms such as “first”, “second”, or the like used in the present application do not indicate any order, number, or importance, but are only to distinguish different parts. The phasing “including”, “comprising”, or the like means that the element or object before the phasing covers the element or object and equivalents thereof listed below the phasing, but does not exclude other elements or objects. The expression such as “connected”, “coupled”, or the like is not limited to physical or mechanical connections, but may include electrical connections, either direct or indirect. “Upper”, “lower”, “left”, “right”, or the like are used only to indicate relative positional relations. When an absolute position of a described object is changed, the relative positional relations may also be changed accordingly.

It should be noted that the embodiments of the present application and the features therein may be combined with each other without contradictory.

### Embodiment I

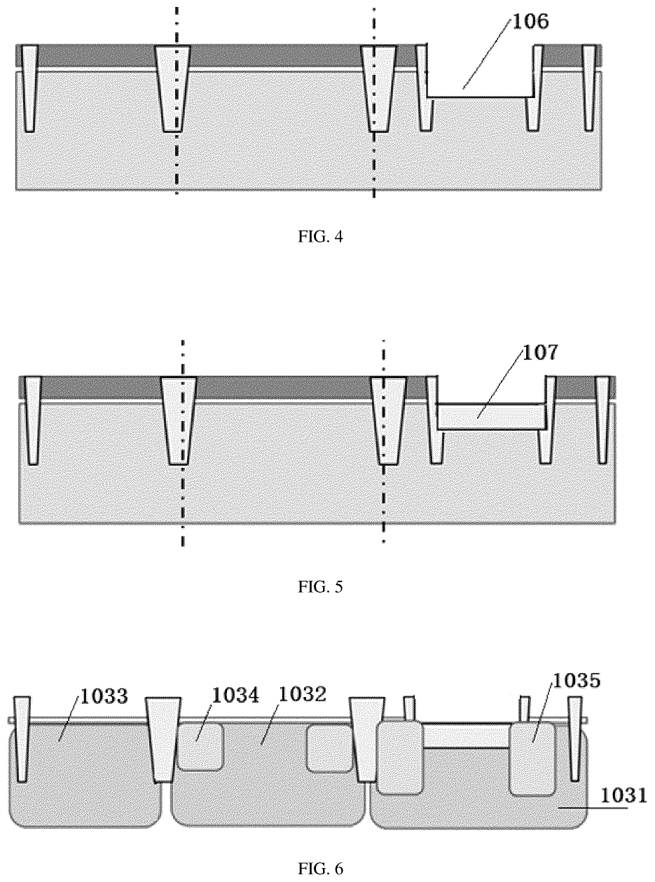

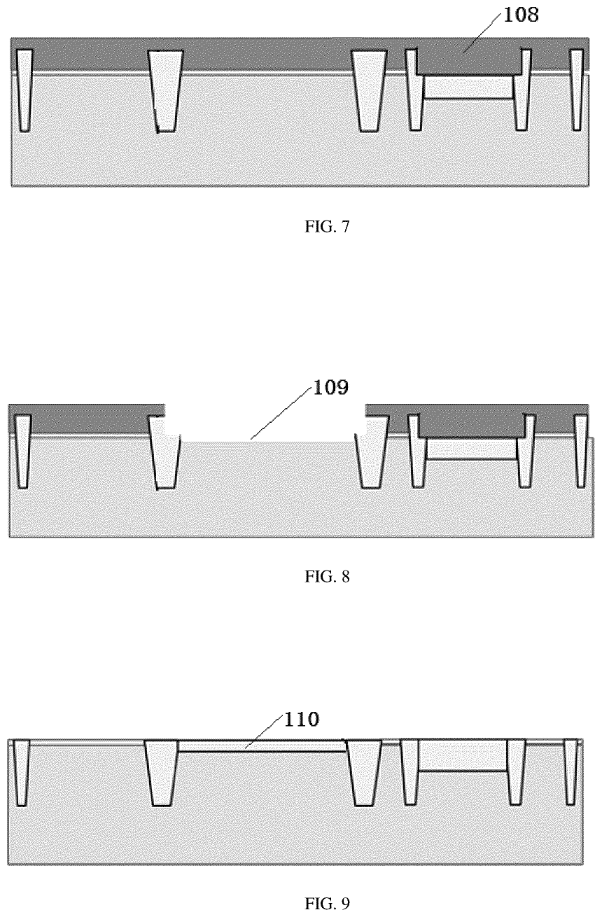

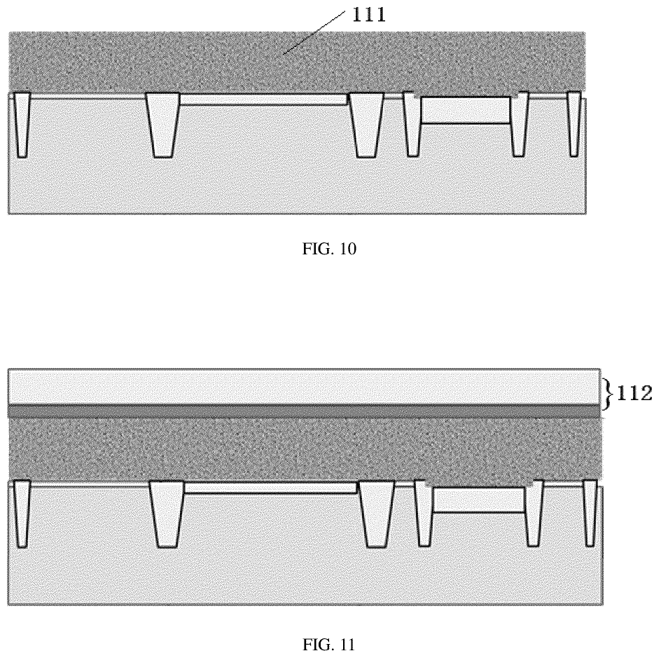

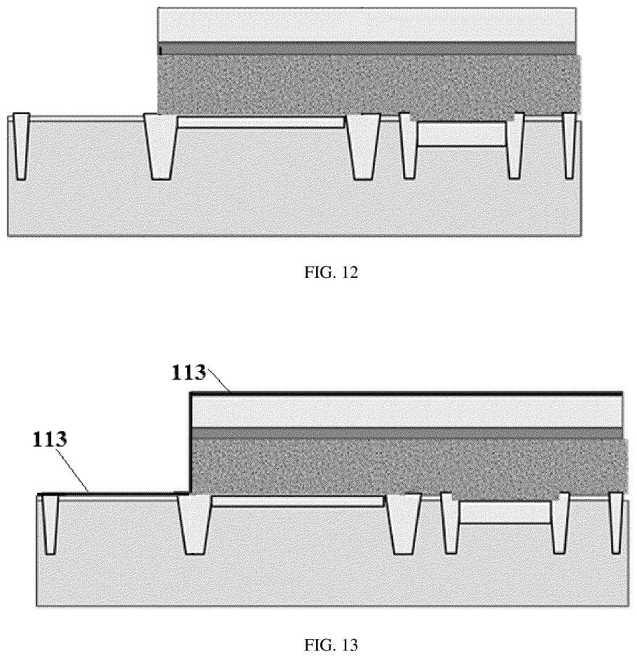

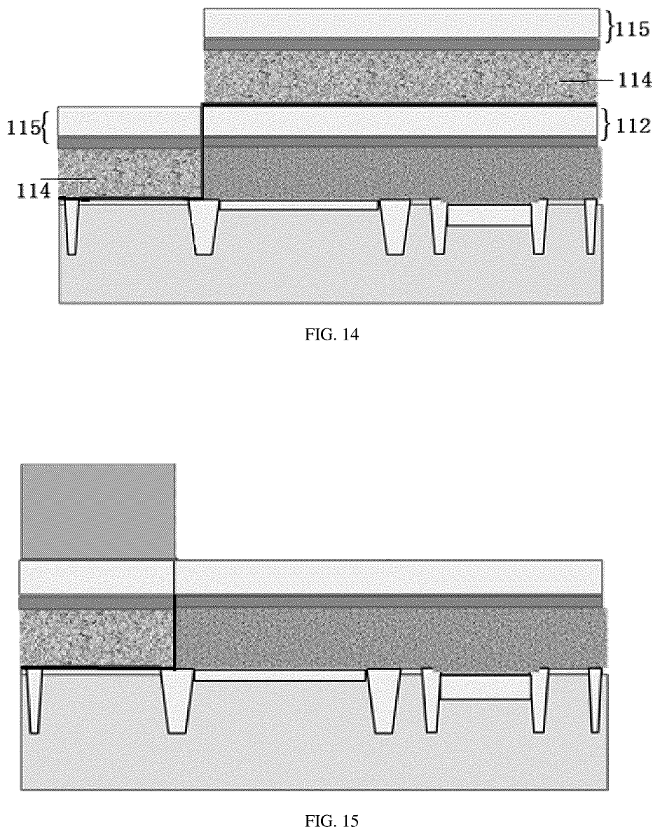

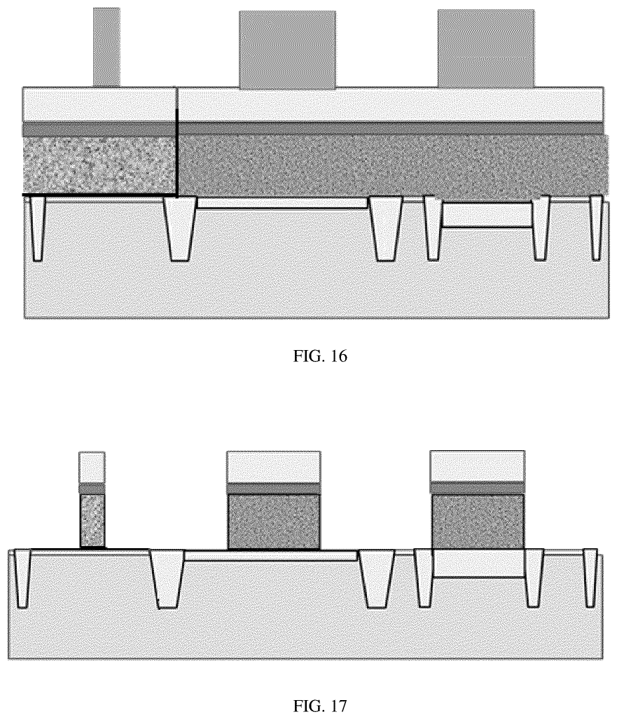

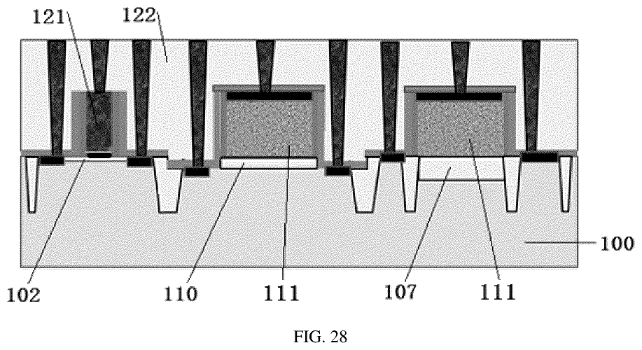

A method for making an integrated structure of an MOS transistor having different operation voltages, comprising the following steps:
S1. forming a pad-oxide 102 on a silicon substrate 100, referring to FIG. 1;
S2. forming a first SIN layer 104 on the pad-oxide 102;
S3. performing a shallow trench isolation process to form a shallow trench isolation STI (Shallow Trench Isolation) 105 dividing a high voltage region, a medium voltage region, and a low voltage region on the silicon substrate 100, referring to FIG. 3;
S4. forming a high voltage region si-recess 106 in the silicon substrate 100 in the high voltage (HV) region, referring to FIG. 4;
S5. performing high voltage gate oxide (HV-Gate oxide) growth, with the upper surface of a high voltage gate oxide (HV-Gate oxide) 107 in the high voltage region si-recess 106 flush with the upper surface of the silicon substrate 100, referring to FIG. 5;
S6. forming a second SIN layer 108 on the silicon substrate 100, referring to FIG. 7;
S7. removing the second SIN layer 108 in the medium voltage region and retaining the second SIN layer 108 in the low voltage region and the high voltage region;
S8. forming a medium voltage region si-recess 109 in the silicon substrate 100 in the medium voltage (MV) region, the depth of the medium voltage region si-recess 109 in the silicon substrate 100 being less than that of the high voltage region si-recess 106, referring to FIG. 8;
S9. performing medium voltage gate oxide (MV-Gate oxide) growth, the upper surface of the medium voltage gate oxide (MV-Gate oxide) 110 within the medium voltage region si-recess 109 being flush with the upper surface of the silicon substrate 100, referring to FIG. 9;
S10. removing the second SIN layer 108;
S11. depositing a first polysilicon layer 111, referring to FIG. 10;
S12. forming a first hard mask layer (HM) 112 on the first polysilicon layer 111, referring to FIG. 11;
S13. performing dry etching to remove the first polysilicon layer 111 in the low voltage (LV) region, referring to FIG. 12; and then depositing a low voltage gate oxide (LV-Gate-oxide) and high-K (HK) constant layer 113, referring to FIG. 13;
S14. deposing a second polysilicon layer 114 and forming a second hard mask layer 115 on the second polysilicon layer 114, the thickness of the second polysilicon layer 114 being consistent with that of the first polysilicon layer 111 (with a difference within 20%), and the thickness of the second hard mask layer 115 being consistent with that of the first hard mask layer 112 (with a difference within 20%);
S15. performing photoetching, and etching, removing the second polysilicon layer 114 in the medium voltage (MV) region and the high voltage (HV) region, and retaining the second polysilicon layer 114 in the low voltage (LV) region, referring to FIG. 15;
S16. performing photoetching, referring to FIG. 16, and etching, and forming a low voltage (LV) region gate stack, a medium voltage (MV) region gate stack and a high voltage (HV) region gate stack, referring to FIG. 17; the heights of the low voltage (LV) region gate stack, medium voltage (MV) region gate stack and high voltage (HV) region gate stack being consistent; the low voltage (LV) region gate stack including, from bottom to top, the pad-oxide 102, the low voltage gate oxide (LV-Gate-oxide) and high-K (HK) constant layer 113, the second polysilicon layer 114, and the second hard mask layer 115; the medium voltage (MV) region gate stack including, from bottom to top, the medium voltage gate oxide (MV-Gate oxide) 110, the first polysilicon layer 111, and the first hard mask layer (HM) 112; and the high voltage (HV) region gate stack including, from bottom to top, the high voltage gate oxide (HV-Gate oxide) 107, the first polysilicon layer 111, and the first hard mask layer (HM) 112;
S17. forming spacers of the low voltage (LV) region gate, the medium voltage (MV) region gate and the high voltage (HV) region gate, referring to FIG. 18; and
S18. performing a subsequent process to form an integrated structure of an MOS transistor having different operation voltages, referring to FIG. 28.

In the method for making an integrated structure of an MOS transistor having different operation voltages of embodiment I, the resulting integrated structure of an MOS transistor employs a hybrid gate solution. A resulting LV (low voltage) MOS transistor adopts HKMG (High-K Metal Gate), so that the gate leakage of the LV (low voltage) MOS transistor can be reduced and speed performance is maintained; and a resulting MV (medium voltage) MOS transistor and a HV (high voltage) MOS transistor adopt a poly gate, the gate oxide is a single oxide, and a high-K film (HK film) is not present, so that the resulting MV (medium voltage) MOS transistor and HV (high voltage) MOS transistor are highly reliable without any other reliability problems due to the introduction of a high-K film (HK film) and a gate metal film.

The method for making an integrated structure of an MOS transistor having different operation voltages in embodiment I is an integrated process method for making an integrated structure of high voltage, medium voltage and low voltage MOS transistors by means of a 28HKMG (28 nm High-K Metal Gate) process platform, effectively improving the compatibility of the high-speed performance of the LV (low voltage) MOS transistor with the high reliability of the MV (medium voltage) MOS transistor and HV (high voltage) MOS transistor made by the same process platform in the same process, and the method can be used for making a highly reliable AMOLED (Active-matrix organic light-emitting diode) display driver chip.

### Embodiment II

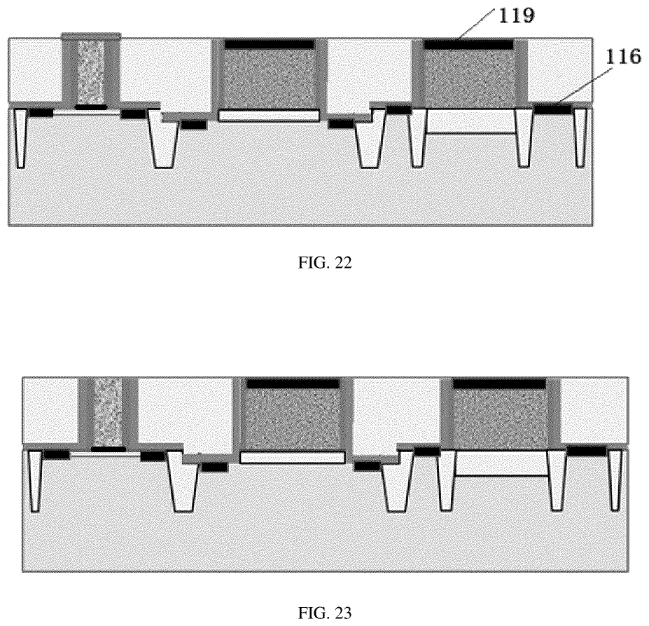

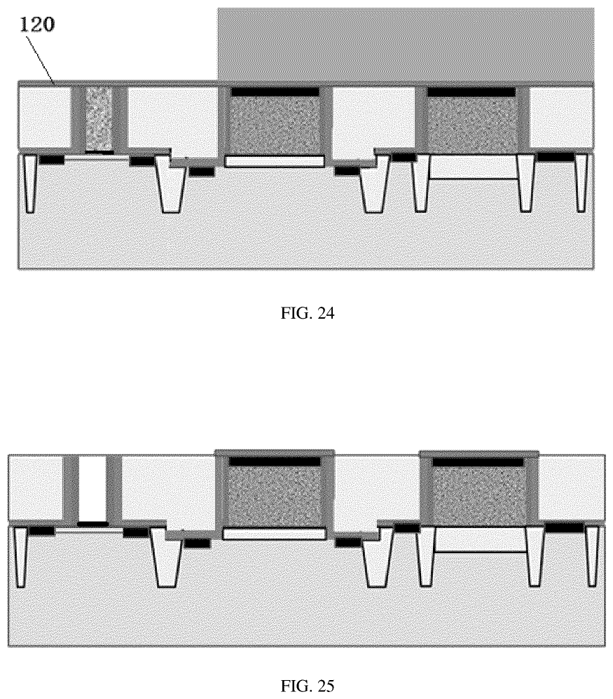

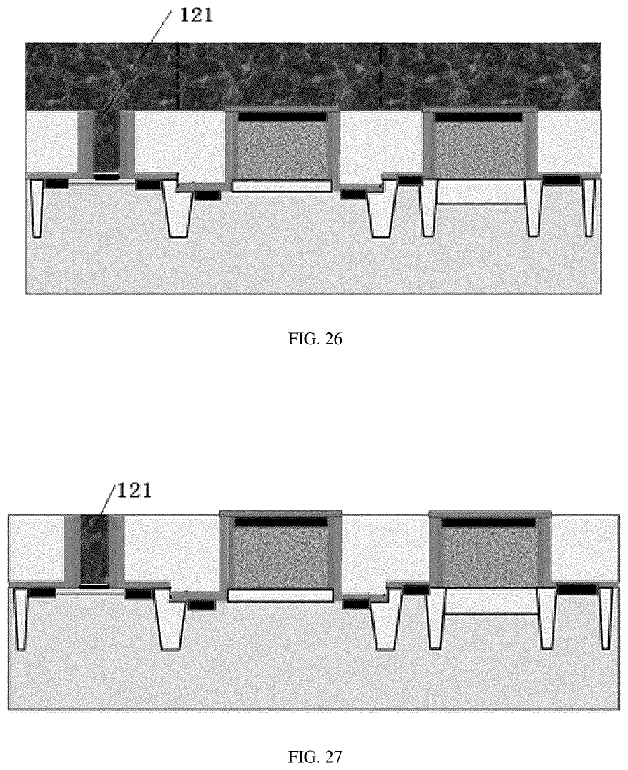

The method for making an integrated structure of an MOS transistor having different operation voltages based on embodiment I, step S18 comprises the following steps:
S180. exposing the upper surface of the second polysilicon layer 114 of the low voltage (LV) region gate, the upper surface of the first polysilicon layer 111 of the medium voltage (MV) region gate, and the upper surface of the first polysilicon layer 111 of the high voltage (MV) region gate;
S181. sequentially depositing a first CESL (Contact Etch Stop Layer) 117, and interlayer dielectric 0 (Interlayer Dielectric 0, ILD0) 118;
S182. performing chemical mechanical polishing CMP, and stopping at the first CESL (Contact Etch Stop Layer) 117, referring to FIG. 20;
S183. performing photoetching, and etching, removing the first CESL (Contact Etch Stop Layer) 117 on the medium voltage (MV) region gate and the high voltage (HV) region gate, exposing the first polysilicon layers 111 of the medium voltage (MV) region gate and the high voltage (HV) region gate, and retaining the first CESL (Contact Etch Stop Layer) 117 on the low voltage (LV) region gate, referring to FIG. 21;
S184. performing a silicide (metal silicide) process to form a gate silicide (metal silicide) 119 on the exposed first polysilicon layers 111 of the medium voltage (MV) region gate and the high voltage (HV) region gate, referring to FIG. 22;
S185. performing wet etching to remove the first CESL (Contact Etch Stop Layer) 117 on the low voltage (LV) region gate, referring to FIG. 23;
S186. depositing a second CESL (Contact Etch Stop Layer) 120, referring to FIG. 24;
S187. performing photoetching, and etching, removing the second CESL (Contact Etch Stop Layer) on the low voltage (LV) region gate and retaining the second CESL (Contact Etch Stop Layer) 120 on the polysilicon layers of the medium voltage (MV) region gate and the high voltage (HV) region gate;
S188. by a DPR (dummy poly removal) process, removing the second polysilicon layer 114 on the low voltage (LV) region gate and exposing low voltage gate oxide (LV-Gate-oxide) and high-K (HK) constant layer 113 at the low voltage (LV) region, referring to FIG. 25;
S189. performing a metal gate loop and filling a gate metal 121 into the groove of the low voltage (LV) region gate surrounded by deposition of the low voltage gate oxide (LV-Gate-oxide) and high-K (HK) constant layer 113 along with a spacer, referring to FIG. 26;
S190. depositing interlayer dielectric 1 (ILD1) 122;
S191. performing a contact process, and a subsequent back-end-of-line (BEOL) process, to form an integrated structure of an MOS transistor having different operation voltages, referring to FIG. 28.

Preferably, in step S1, the pad-oxide 102 is further formed with a zero mark as an alignment layer for subsequent layer photoetching.

Preferably, in step S2, ion implantation is first performed in the silicon substrate 100 in the high voltage region to form a high voltage region well (HV-Well) 1031, referring to FIG. 2, and then the first SIN layer 104 is formed on the pad-oxide 102.

Preferably, in step S3, the shallow trench isolation (STI) 105 is formed, and then chemical mechanical polishing (CMP) is performed.

Preferably, in step S4, the high voltage region si-recess 106 has the depth of 400 Å-500 Å in the silicon substrate 100; and

in step S9, the medium voltage region si-recess 109 has the depth of 100 Å-200 Å (e.g. 150 Å) in the silicon substrate 100.

Preferably, in step S6, the first SIN layer 104 is first removed, then ion implantation is performed for the silicon substrate 100 in the medium voltage region and the low voltage region to form the medium Voltage region well (MV-Well) 1032 and the low voltage region well (LV-Well) 1033, referring to FIG. 6, and finally, the second SIN layer 108 is formed on the silicon substrate 100.

Preferably, in step S6, the first SIN layer 104 is first removed, then ion implantation is performed for the silicon substrate 100 in the medium voltage region and the low voltage region to form the medium Voltage region well (MV-Well) 1032 and the low voltage region well (LV-Well) 1033, then ion implantation is performed for a medium voltage region Lightly-Doped drain (MV LDD) 1034 and a high voltage region Lightly-Doped drain (HV LDD) 1035, and finally, the second SIN layer (108) is formed on the silicon substrate (100).

Preferably, in step S11, doping ion implantation is performed for the first polysilicon layer 111.

Preferably, the first hard mask layer 112 is a laminated structure of SiN and silicon oxide; and

the second hard mask layer 115 is a laminated structure of SiN and silicon oxide.

Preferably, in step S17, ion implantation for a low voltage lightly-doped drain (LV LDD) is performed first, then spacers for the low voltage (LV) region gate, the medium voltage (MV) region gate and the high voltage (HV) region gate are formed, referring to FIG. 18; then an SDN (source-drain N heavily-doped) ion implantation is performed; and finally, a source-drain metal silicide (salicide) 116 is formed, referring to FIG. 19.

Preferably, in step S189, the metal gate loop comprises work function layer and metal deposition.

Preferably, in step S190, chemical mechanical polishing is first performed for the gate metal 121, the gate in the medium voltage (MV) region, and the high voltage (HV) region stop at the second CESL (Contact Etch Stop Layer) 120, and the low voltage (LV) region gate stops at the interlayer dielectric 0 (ILD0) 118, referring to FIG. 27; and then the interlayer dielectric 1 (ILD1) 122 is deposited, referring to FIG. 28.

Preferably, the first CESL (Contact Etch Stop Layer) 117 and the second CESL (Contact Etch Stop Layer) 120 are both SiN.

### Embodiment III

An integrated structure of an MOS transistor having different operation voltages, referring to FIG. 28, has a high voltage MOS transistor, a medium voltage MOS transistor, and a low voltage MOS transistor formed on the same silicon substrate 100;
the operation voltage of the high voltage MOS transistor is greater than that of the medium voltage MOS transistor, and the operation voltage of the medium voltage MOS transistor is greater than that of the low voltage MOS transistor;
the gate stack structure of the high voltage MOS transistor includes a high voltage gate oxide 107, and a first polysilicon layer 111 stacked sequentially from bottom to top; and
the high voltage gate oxide 107 is formed in the silicon substrate 100, and the upper surface of the high voltage gate oxide 107 is flush with the upper surface of the silicon substrate 100;
the gate stack structure of the medium voltage MOS transistor includes a medium voltage gate oxide 110, and a first polysilicon layer 111 stacked sequentially from bottom to top; the medium voltage gate oxide 110 is formed in the silicon substrate 100, and the upper surface of the medium voltage gate oxide 110 is flush with the upper surface of the silicon substrate 100; and the thickness of the medium voltage gate oxide 110 is less than that of the high voltage gate oxide 107; and
the gate stack structure of the low voltage MOS transistor comprises a pad-oxide 102, and a gate metal 121 stacked sequentially from bottom to top; and the pad-oxide 102 covers the upper surface of the silicon substrate 100.

Preferably, the gate stack structure of the low voltage MOS transistor comprises the pad-oxide 102, a low voltage gate oxide and high-K constant layer 113 deposition, and a gate metal 121 stacked sequentially from bottom to top; and the pad-oxide 102 covers the upper surface of the silicon substrate 100.

Preferably, the gate end of the high voltage MOS transistor is connected to the upper end of the first polysilicon layer 111 of the gate stack structure thereof by means of a contact hole;
the gate end of the medium voltage MOS transistor is connected to the upper end of the first polysilicon layer 111 of the gate stack structure thereof by means of the contact hole; and
the gate end of the low voltage MOS transistor is connected to the upper end of the gate metal 121 of the gate stack structure thereof by means of the contact hole.

Preferably, the upper ends of the first polysilicon layers 111 of the gate stack structures of the gate ends of the high voltage MOS transistor and medium voltage MOS transistor are formed with the gate metal silicide 119;
the gate end of the high voltage MOS transistor is connected to the upper end of the gate metal silicide 119 on the gate stack structure thereof by means of the contact hole; and
the gate end of the medium voltage MOS transistor is connected to the upper end of the gate metal silicide 119 on the gate stack structure thereof by means of the contact hole.

Preferably, the high voltage gate oxide 107 has a thickness of 400 Å-500 Å (for example, 460 Å), and the medium voltage gate oxide 110 has a thickness of 100 Å-200 Å (for example, 150 Å).

In the integrated structure of the MOS transistor having different operation voltages of embodiment III, a hybrid gate solution is used for the high voltage MOS transistor, the medium voltage MOS transistor, and the low voltage MOS transistor. The LV (low voltage) MOS transistor adopts an HKMG (High-K Metal Gate), so that the gate leakage of the LV (low voltage) MOS transistor can be reduced and speed performance can be maintained. The MV (medium voltage) MOS transistor and HV (high voltage) MOS transistor adopt poly gates, and the gate oxide is a single oxide without high-K film (HK film), so that the MV (medium voltage) MOS transistor and HV (high voltage) MOS transistor are highly reliable without any other reliability problems due to the introduction of a high-K film (HK film) and a gate metal film. The integrated structure of an MOS transistors having different operation voltages can be made by means of a 28HKMG (28 nm High-K Metal Gate) process platform.

The embodiments described above are only preferred embodiments of the present application and are not intended to limit the present application. The scope of protection of the application shall include any modifications, equivalent substitutions, improvements, etc. made within the spirit and principle of the present application.

What is claimed is:

1. A method of making an integrated structure of an MOS transistor having different operation voltages, comprising the following steps:
S1: forming a pad-oxide (102) on a silicon substrate (100);
S2: forming a first SIN layer (104) on the pad-oxide (102);
S3: performing a shallow trench isolation process to form a shallow trench isolation (105) dividing a high voltage region, a medium voltage region, and a low voltage region on the silicon substrate (100);
S4: forming a high voltage region si-recess (106) in the silicon substrate (100) in the high voltage region;
S5: performing high voltage gate oxide growth, an upper surface of a high voltage gate oxide (107) in the high voltage region si-recess (106) being flush with an upper surface of the silicon substrate (100);
S6: forming a second SIN layer (108) on the silicon substrate (100);
S7: removing the second SIN layer (108) in the medium voltage region and retaining the second SIN layer (108) in the low voltage region and the high voltage region;
S8: forming a medium voltage region si-recess (109) in the silicon substrate (100) in the medium voltage region, a depth of the medium voltage region si-recess (109) in the silicon substrate (100) being less than that of the high voltage region si-recess (106);
S9: performing medium voltage gate oxide growth, an upper surface of a medium voltage gate oxide (110) within the medium voltage region si-recess (109) being flush with the upper surface of the silicon substrate (100);
S10: removing the second SIN layer (108);
S11: depositing a first polysilicon layer (111);
S12: forming a first hard mask layer (112) on the first polysilicon layer (111);
S13: performing dry etching to remove the first polysilicon layer (111) in the low voltage region; and then depositing a low voltage gate oxide and high-K constant layer (113);
S14: deposing a second polysilicon layer (114) and forming a second hard mask layer (115) on the second polysilicon layer (114), a thickness of the second polysilicon layer (114) being consistent with that of the first polysilicon layer (111), and a thickness of the second hard mask layer (115) being consistent with that of the first hard mask layer (112);
S15: performing photoetching, and etching, removing the second polysilicon layer (114) in the medium voltage region and the high voltage region, and retaining the second polysilicon layer (114) in the low voltage region;
S16: performing photoetching, and etching, and forming a low voltage region gate stack, a medium voltage region gate stack and a high voltage region gate stack; heights of the low voltage region gate stack, medium voltage region gate stack and high voltage region gate stack being consistent; the low voltage region gate stack including, from bottom to top, the pad-oxide (102), the low voltage gate oxide and high-K constant layer (113), the second polysilicon layer (114), and the second hard mask layer (115); the medium voltage region gate stack including, from bottom to top, the medium voltage gate oxide (110), the first polysilicon layer (111), and the first hard mask layer (112); and the high voltage region gate stack including, from bottom to top, the high voltage gate oxide (107), the first polysilicon layer (111), and the first hard mask layer (112);
S17: forming spacers of a low voltage region gate, a medium voltage region gate, and a high voltage region gate; and
S18: performing a subsequent process to form the integrated structure of the MOS transistor having different operation voltages.

2. The method for making the integrated structure of the MOS transistor having different operation voltages according to claim 1, wherein step S18 comprises the following steps:
S180: exposing an upper surface of the second polysilicon layer (114) of the low voltage region gate, an upper surface of the first polysilicon layer (111) of the medium voltage region gate, and the upper surface of the first polysilicon layer (111) of the high voltage region gate;
S181: sequentially depositing a first contact etch stop layer (117), and interlayer dielectric 0 (118);
S182: performing chemical mechanical polishing, and stopping at the first contact etch stop layer (117);
S183: performing photoetching, and etching, removing the first contact etch stop layer (117) on the medium voltage region gate and the high voltage region gate, exposing the first polysilicon layers (111) of the medium voltage region gate and the high voltage region gate, and retaining the first contact etch stop layer (117) on the low voltage region gate;
S184: performing a metal silicide process to form a gate metal silicide (119) on the exposed first polysilicon layers (111) of the medium voltage region gate and the high voltage region gate;
S185: performing wet etching to remove the first contact etch stop layer (117) on the low voltage region gate;
S186: depositing a second contact etch stop layer (120);
S187: performing photoetching, and etching, removing the second contact etch stop layer on the low voltage region gate and retaining the second contact etch stop layer (120) on the polysilicon layers of the medium voltage region gate and the high voltage region gate;
S188: by a dummy poly removal process, removing the second polysilicon layer (114) on the low voltage region gate and exposing low voltage gate oxide and high-K constant layer (113) deposition at the low voltage region;
S189: performing a metal gate loop and filling a gate metal (121) into a groove of the low voltage region gate surrounded by the low voltage gate oxide and high-K constant layer (113) deposition along with a spacer;
S190: depositing interlayer dielectric 1 (122); and
S191: performing a contact process, and a subsequent back-end-of-line process, to form the integrated structure of the MOS transistor having different operation voltages.

3. The method for making the integrated structure of the MOS transistor having different operation voltages according to claim 1, wherein, in step S1, the pad-oxide (102) is further formed with a zero mark as an alignment layer for subsequent layer photoetching.

4. The method for making the integrated structure of the MOS transistor having different operation voltages according to claim 1, wherein, in step S2, ion implantation is first performed in the silicon substrate (100) in the high voltage region to form a high voltage region well (1031), and then the first SIN layer (104) is formed on the pad-oxide (102).

5. The method for making the integrated structure of the MOS transistor having different operation voltages according to claim 1, wherein, in step S3, the shallow trench isolation (105) is formed, and then chemical mechanical polishing is performed.

6. The method for making the integrated structure of the MOS transistor having different operation voltages according to claim 1, wherein,
in step S4, the high voltage region si-recess (106) has a depth of 400 Å-500 Å in the silicon substrate (100); and
in step S9, the medium voltage region si-recess (109) has a depth of 100 Å-200 Å in the silicon substrate (100).

7. The method for making the integrated structure of the MOS transistor having different operation voltages according to claim 1, wherein, in step S6, the first SIN layer (104) is first removed, then ion implantation is performed for the silicon substrate (100) in the medium voltage region and the low voltage region to form the medium voltage region well (1032) and the low voltage region well (1033), and finally, the second SIN layer (108) is formed on the silicon substrate (100).

8. The method for making the integrated structure of the MOS transistor having different operation voltages according to claim 1, wherein, in step S6, the first SIN layer (104) is first removed, then ion implantation is performed for the silicon substrate (100) in the medium voltage region and the low voltage region to form the medium voltage region well (1032) and the low voltage region well (1033), then ion implantation is performed for a medium voltage region lightly-doped drain (1034) and a high voltage region lightly-doped drain (1035), and finally, the second SIN layer (108) is formed on the silicon substrate (100).

9. The method for making the integrated structure of the MOS transistor having different operation voltages according to claim 1, wherein, in step S11, doping ion implantation is performed for the first polysilicon layer (111).

10. The method for making the integrated structure of the MOS transistor having different operation voltages according to claim 1, wherein the first hard mask layer (112) is a laminated structure of SiN and silicon oxide, and the second hard mask layer (115) is a laminated structure of SiN and silicon oxide.

11. The method for making the integrated structure of the MOS transistor having different operation voltages according to claim 1, wherein, in step S17, ion implantation for a low voltage lightly-doped drain is performed first, then spacers for the low voltage region gate, the medium voltage region gate, and the high voltage region gate are formed; then a source-drain N heavily-doped ion implantation is performed; and finally, a source-drain metal silicide (116) is formed.

12. The method for making the integrated structure of the MOS transistor having different operation voltages according to claim 2, wherein, in step S189, the metal gate loop comprises work function layer and metal deposition.

13. The method for making the integrated structure of the MOS transistor having different operation voltages according to claim 2, wherein, in step S190, chemical mechanical polishing is first performed for the gate metal (121), the gate in the medium voltage region, and the high voltage region stop at the second contact etch stop layer (120), and the low voltage region gate stops at the interlayer dielectric 0 (118); and then the interlayer dielectric 1 (122) is deposited.

14. The method for making the integrated structure of the MOS transistor having different operation voltages according to claim 2, wherein the first contact etch stop layer (117) and the second contact etch stop layer (120) are both SiN.

15. The method for making the integrated structure of the MOS transistor having different operation voltages according to claim 1, wherein the method is a method for making an integrated structure of an MOS transistor having different operation voltages based on a 28 nm high-K metal gate (28HKMG) process platform.

16. An integrated structure of an MOS transistor having different operation voltages, wherein a high voltage MOS transistor, a medium voltage MOS transistor, and a low voltage MOS transistor are formed on the same silicon substrate (100);
an operation voltage of the high voltage MOS transistor is greater than that of the medium voltage MOS transistor, and an operation voltage of the medium voltage MOS transistor is greater than that of the low voltage MOS transistor;
a gate stack structure of the high voltage MOS transistor includes a high voltage gate oxide (107), and a first polysilicon layer (111) stacked sequentially from bottom to top; and the high voltage gate oxide (107) is formed in the silicon substrate (100), and an upper surface of the high voltage gate oxide (107) is flush with an upper surface of the silicon substrate (100);
the gate stack structure of the medium voltage MOS transistor includes a medium voltage gate oxide (110), and a first polysilicon layer (111) stacked sequentially from bottom to top; the medium voltage gate oxide (110) is formed in the silicon substrate (100), and an upper surface of the medium voltage gate oxide (110) is flush with the upper surface of the silicon substrate (100); and a thickness of the medium voltage gate oxide (110) is less than that of the high voltage gate oxide (107); and
the gate stack structure of the low voltage MOS transistor comprises a pad-oxide (102), and a gate metal (121) stacked sequentially from bottom to top; and the pad-oxide (102) covers the upper surface of the silicon substrate (100).

17. The integrated structure of the MOS transistor having different operation voltages according to claim 16, wherein the gate stack structure of the low voltage MOS transistor comprises the pad-oxide (102), a low voltage gate oxide and high-K constant layer (113) deposition, and a gate metal (121) stacked sequentially from bottom to top; and the pad-oxide (102) covers the upper surface of the silicon substrate (100).

18. The integrated structure of the MOS transistor having different operation voltages according to claim 16, wherein,
the gate end of the high voltage MOS transistor is connected to an upper end of the first polysilicon layer (111) of the gate stack structure thereof by means of a contact hole;
the gate end of the medium voltage MOS transistor is connected to the upper end of the first polysilicon layer (111) of the gate stack structure thereof by means of the contact hole; and
the gate end of the low voltage MOS transistor is connected to an upper end of the gate metal (121) of the gate stack structure thereof by means of the contact hole.

19. The integrated structure of the MOS transistor having different operation voltages according to claim 16, wherein,
the upper ends of the first polysilicon layers (111) of the gate stack structures of the gate ends of the high voltage MOS transistor and medium voltage MOS transistor are formed with a gate metal silicide (119);
the gate end of the high voltage MOS transistor is connected to an upper end of the gate metal silicide (119) on the gate stack structure thereof by means of a contact hole; and
the gate end of the medium voltage MOS transistor is connected to the upper end of the gate metal silicide (119) on the gate stack structure thereof by means of the contact hole.

20. The integrated structure of the MOS transistor having different operation voltages according to claim 16, wherein the high voltage gate oxide (107) has a thickness of 400 Å-500 Å and the medium voltage gate oxide (110) has a thickness of 100 Å-200 Å.
